(19) United States
(12) Patent Application Publication
(10) Pub. No.: US 2022/0344390 A1
(43) Pub. Date: Oct. 27, 2022

(54) ORGANIC CIS IMAGE SENSOR

(71) Applicants: SONY SEMICONDUCTOR SOLUTIONS CORPORATION, Kanagawa (JP); SONY GROUP CORPORATION, Tokyo (JP)

(72) Inventors: Akira FURUKAWA, Kanagawa (JP); Sho NISHIDA, Tokyo (JP); Hideaki TOGASHI, Kanagawa (JP); Takushi SHIGETOSHI, Kanagawa (JP); Shinpei FUKUOKA, Kanagawa (JP); Junpei YAMAMOTO, Kanagawa (JP)

(21) Appl. No.: 17/772,907

(22) PCT Filed: Jul. 27, 2020
(86) PCT No.: PCT/JP2020/028664

§ 371 Date: Apr. 28, 2022

(30) Foreign Application Priority Data
Oct. 29, 2019 (JP) 2019-196273

(51) Int. Cl. H01L 27/146; H04N 5/361; H04N 5/369; H01L 27/148

(52) U.S. Cl. CPC H01L 27/14605; H04N 5/361; H04N 5/369; H01L 27/14806

(57) ABSTRACT

To reduce a dark current of an image sensor including a photoelectric conversion unit disposed on a back surface of a semiconductor substrate.

The image sensor includes a photoelectric conversion unit, a through-electrode, a charge holding unit, a back-side high impurity concentration region, and a front-side high impurity concentration region. The photoelectric conversion unit is disposed on a back surface of a semiconductor substrate and performs photoelectric conversion of incident light. The through-electrode is formed in a shape penetrating from the back surface to a front surface of the semiconductor substrate and transmits a charge generated by the photoelectric conversion. The charge holding unit is disposed on the front surface of the semiconductor substrate and holds the transmitted charge. The back-side high impurity concentration region is disposed in a region adjacent to the through-electrode on the back surface of the semiconductor substrate and is formed to have a higher impurity concentration than an impurity concentration of a region adjacent to the through-electrode at the central portion of the semiconductor substrate. The front-side high impurity concentration region is disposed in a region adjacent to the through-electrode on the front surface of the semiconductor substrate and is formed to have a higher impurity concentration than the impurity concentration of the region adjacent to the through-electrode at the central portion of the semiconductor substrate.

### TECHNICAL FIELD

The present disclosure relates to an image sensor and an imaging apparatus. Specifically, the present disclosure relates to an image sensor in which an electrode penetrating through a semiconductor substrate is disposed, and to an imaging apparatus using the image sensor.

### BACKGROUND ART

A back-illuminated image sensor in which the back surface of a semiconductor substrate is irradiated with incident light has been conventionally used. For example, the following image sensor is used, in which a photoelectric conversion unit having an organic photoelectric conversion material is disposed on the back surface of the semiconductor substrate, and a drive circuit for generating an image signal on the basis of a charge generated by the photoelectric conversion unit is disposed on the front surface of the semiconductor substrate (see, for example, Patent Literature 1). In such an image sensor, the charge generated in the back surface of the semiconductor substrate is transmitted to the drive circuit disposed on the front surface via a contact hole portion, which is an electrode penetrating through the semiconductor substrate, so that an image signal is generated.

### CITATION LIST

### Patent Literature

Patent Literature 1: Japanese Patent Application Laid-open No. 2017-157816

### DISCLOSURE OF INVENTION

### Technical Problem

In the related art described above, there is a problem that noise of the image signal increases. The contact hole portion is constituted by embedding a conductive material such as metal in a through-hole formed in the semiconductor substrate. When the through-hole is formed, crystal defects are caused in the semiconductor substrate. The current (called dark current) due to supplementation or emission of a charge at the trap level caused by such crystal defects is superimposed on the image signal, thus causing noise in the image signal. Therefore, in the related art described above, there is a problem that the image quality of the image based on the image signal generated by the image sensor is reduced.

The present disclosure has been made in view of the problems described above, and an object thereof is to reduce noise by reducing the dark current of the image sensor including the photoelectric conversion unit disposed on the back surface of the semiconductor substrate, and to prevent the image quality from being deteriorated.

### Solution to Problem

The present disclosure has been made to solve the problems described above, and a first aspect thereof is an image sensor including: a photoelectric conversion unit that is disposed on a back surface of a semiconductor substrate and performs photoelectric conversion of incident light; a through-electrode that is formed in a shape penetrating from the back surface to a front surface of the semiconductor substrate and transmits a charge generated by the photoelectric conversion; a charge holding unit that is disposed on the front surface of the semiconductor substrate and holds the transmitted charge; a back-side high impurity concentration region that is disposed in a region adjacent to the through-electrode on the back surface of the semiconductor substrate and is formed to have a higher impurity concentration than an impurity concentration of a region adjacent to the through-electrode at the central portion of the semiconductor substrate; and a front-side high impurity concentration region that is disposed in a region adjacent to the through-electrode on the front surface of the semiconductor substrate and is formed to have a higher impurity concentration than the impurity concentration of the region adjacent to the through-electrode at the central portion of the semiconductor substrate.

Further, in the first aspect, the photoelectric conversion unit may include a photoelectric conversion film disposed adjacent to the back surface of the semiconductor substrate.

Further, in the first aspect, the through-electrode may be formed by embedding a conductive material in a through-hole, the through-hole being formed in the semiconductor substrate and including an insulating film disposed on a wall surface thereof.

Further, in the first aspect, the front-side high impurity concentration region may be formed to have an impurity concentration of substantially 10¹⁷ cm⁻³ or more.

Further, in the first aspect, the back-side high impurity concentration region may be formed to have an impurity concentration of substantially 10¹⁸ cm⁻³ or more.

Further, in the first aspect, the front-side high impurity concentration region may be formed to have a thickness of substantially ⅙ of a thickness of the semiconductor substrate.

Further, in the first aspect, the back-side high impurity concentration region may be formed to have a thickness of substantially ⅙ of a thickness of the semiconductor substrate.

Further, in the first aspect, the front-side high impurity concentration region may be formed in a cylindrical shape surrounding the through-electrode and having a width equal to or larger than a diameter of the through-electrode.

Further, in the first aspect, the back-side high impurity concentration region may be formed in a cylindrical shape surrounding the through-electrode and having a width equal to or larger than a diameter of the through-electrode.

Further, in the first aspect, the semiconductor substrate may include a region formed to have an impurity concentration of substantially 10¹⁶ cm⁻³ or more, the region being adjacent to the through-electrode between the front-side high impurity concentration region and the back-side high impurity concentration region.

Further, in the first aspect, the image sensor may further include an image signal generation circuit that generates an image signal on the basis of the held charge.

Further, a second aspect is an imaging apparatus including: a photoelectric conversion unit that is disposed on a back surface of a semiconductor substrate and performs photoelectric conversion of incident light; a through-electrode that is formed in a shape penetrating from the back surface to a front surface of the semiconductor substrate and transmits a charge generated by the photoelectric conversion; a holding unit that is disposed on the front surface of the semiconductor substrate and holds the transmitted charge; a back-side high impurity concentration region that is disposed in a region adjacent to the through-electrode on the back surface of the semiconductor substrate and is formed to have a higher impurity concentration than an impurity concentration of a region adjacent to the through-electrode at the central portion of the semiconductor substrate; a front-side high impurity concentration region that is disposed in a region adjacent to the through-electrode on the front surface of the semiconductor substrate and is formed to have a higher impurity concentration than the impurity concentration of the region adjacent to the through-electrode at the central portion of the semiconductor substrate; and a processing circuit that processes an image signal generated on the basis of the held charge.

The aspects described above are adopted, and thus there is an effect that regions having a high impurity concentration are respectively disposed on the front surface and the back surface of the semiconductor substrate in the vicinity of the through-electrode. It is assumed that the influence of crystal defects due to the region having a high impurity concentration is reduced.

### BRIEF DESCRIPTION OF DRAWINGS

FIG. 1 is a diagram showing a configuration example of an image sensor according to an embodiment of the present disclosure.

FIG. 2 is a diagram showing a configuration example of a pixel according to the embodiment of the present disclosure.

FIG. 3 is a cross-sectional diagram showing a configuration example of a pixel according to a first embodiment of the present disclosure.

FIG. 4 is a diagram showing an example of a method of producing an image sensor according to the first embodiment of the present disclosure.

FIG. 5 is a diagram showing the example of the method of producing the image sensor according to the first embodiment of the present disclosure.

FIG. 6 is a diagram showing the example of the method of producing the image sensor according to the first embodiment of the present disclosure.

FIG. 7 is a diagram showing configuration examples of a front-side high impurity concentration region and a back-side high impurity concentration region according to a second embodiment of the present disclosure.

FIG. 8 is a cross-sectional diagram showing a configuration example of a pixel according to a third embodiment of the present disclosure.

FIG. 9 is a cross-sectional diagram showing a configuration example of a pixel according to a fourth embodiment of the present disclosure.

FIG. 10 is a block diagram showing a schematic configuration example of a camera that is an example of an imaging apparatus to which the present technology can be applied.

FIG. 11 is a view depicting an example of a schematic configuration of an endoscopic surgery system.

FIG. 12 is a block diagram depicting an example of a functional configuration of a camera head and a camera control unit (CCU).

FIG. 13 is a block diagram depicting an example of schematic configuration of a vehicle control system.

FIG. 14 is a diagram of assistance in explaining an example of installation positions of an outside-vehicle information detecting section and an imaging section.

### MODE(S) FOR CARRYING OUT THE INVENTION

Next, embodiments for carrying out the present disclosure (hereinafter, referred to as embodiments) will be described with reference to the drawings. In the following drawings, the same or similar portions will be denoted by the same or similar reference symbols. Further, the embodiments will be described in the following order.

1. First Embodiment

2. Second Embodiment

3. Third Embodiment

4. Fourth Embodiment

5. Application Example to Camera

6. Application Example to Endoscopic Surgery System

7. Application Example to Mobile Body

### 1. First Embodiment

[Configuration of Image Sensor]

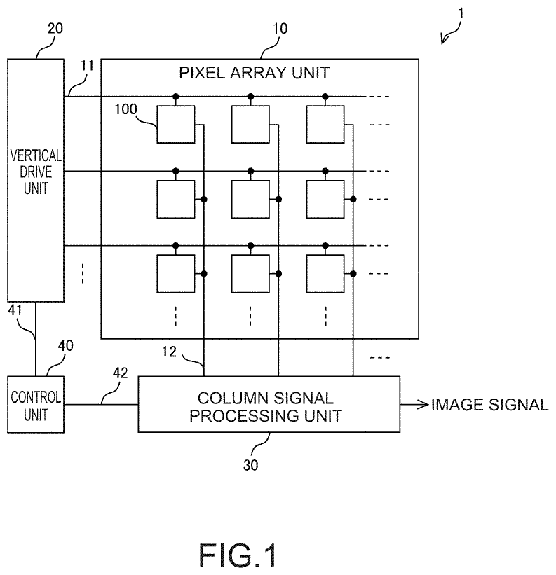

FIG. 1 is a diagram showing a configuration example of an image sensor according to an embodiment of the present disclosure. An image sensor 1 in the figure includes a pixel array unit 10, a vertical drive unit 20, a column signal processing unit 30, and a control unit 40.

The pixel array unit 10 is formed by arranging pixels 100 in a two-dimensional grid pattern. Here, the pixels 100 generate image signals corresponding to applied light. The pixels 100 each include a photoelectric conversion unit for generating charges corresponding to the applied light. Further, the pixels 100 each further include a pixel circuit. This pixel circuit generates an image signal based on the charges generated by the photoelectric conversion unit. The generation of the image signal is controlled by a control signal generated by the vertical drive unit 20 to be described below. In the pixel array unit 10, signal lines 11 and 12 are arranged in an X-Y matrix pattern. The signal line 11 is a signal line for transmitting the control signal for the pixel circuit in the pixel 100, arranged for each row of the pixel array unit 10, and commonly wired to the pixels 100 arranged in each row. The signal line 12 is a signal line for transmitting the image signal generated by the pixel circuit of the pixel 100, arranged for each column of the pixel array unit 10, and commonly wired to the pixels 100 arranged in each column. The photoelectric conversion unit and the pixel circuit are formed in a semiconductor substrate.

The vertical drive unit 20 generates control signals for the pixel circuits of the pixels 100. This vertical drive unit 20 transmits the generated control signals to the pixels 100 via the signal lines 11 in the figure. The column signal processing unit 30 processes the image signals generated by the pixels 100. This column signal processing unit 30 processes the image signals transmitted from the pixels 100 via the signal lines 12 in the figure. For example, analog-to-digital conversion in which an analog image signal generated in the pixel 100 is converted into a digital image signal corresponds to the processing in the column signal processing unit 30. The image signal processed by the column signal processing unit 30 is output as an image signal of the image sensor 1. The control unit 40 controls the entire image sensor 1. This control unit 40 controls the image sensor 1 by generating and outputting control signals for controlling the vertical drive unit 20 and the column signal processing unit 30. The control signals generated by the control unit 40 are transmitted to the vertical drive unit 20 and the column signal processing unit 30 by signal lines 41 and 42, respectively. Note that the column signal processing unit 30 is an example of the processing circuit described in the claims.

[Configuration of Pixel]

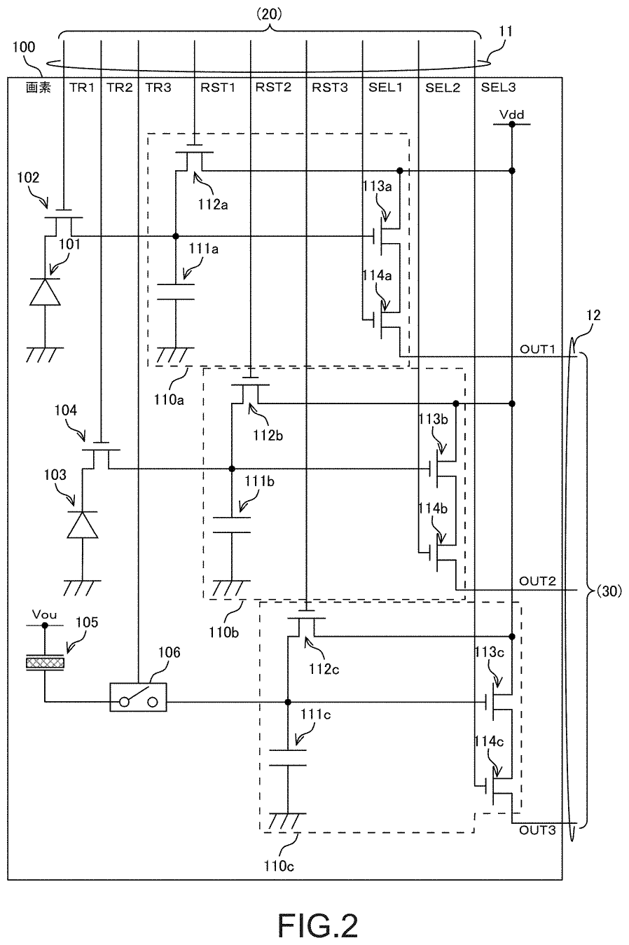

FIG. 2 is a diagram showing a configuration example of a pixel according to the embodiment of the present disclosure. This figure is a circuit diagram showing a configuration example of the pixel 100. The pixel 100 of the figure includes photoelectric conversion units 101, 103, and 105, charge transfer units 102, 104, and 106, and image signal generation circuits 110a, 110b, and 110c. The pixel 100 of the figure includes the three photoelectric conversion units 101, 103, and 105. The charge transfer units 102, 104, and 106 are connected to the photoelectric conversion units 101, 103, and 105, respectively. The image signal generation circuits 110a, 110b, and 110c are connected to the charge transfer units 102, 104, and 106, respectively.

First, a circuit including the photoelectric conversion unit 101, the charge transfer unit 102, and the image signal generation circuit 110a will be described.

The photoelectric conversion unit 101 generates charges corresponding to applied light as described above. A photodiode may be used for the photoelectric conversion unit 101.

The charge transfer unit 102 transfers the charges generated by the photoelectric conversion unit 101. For example, an n-channel MOS transistor can be used for the charge transfer unit 102.

The image signal generation circuit 110a is a circuit for generating image signals on the basis of the charges transferred by the charge transfer unit 102. The image signal generation circuit 110a includes a charge holding unit 111a and MOS transistors 112a, 113a, and 114a.

The circuit formed by the MOS transistors 112a, 113a, and 114a is a circuit for generating image signals on the basis of the charges held in the charge holding unit 111a. N-channel MOS transistors can be used for those MOS transistors.

The anode of the photoelectric conversion unit 101 is grounded, and the cathode thereof is connected to the source of the charge transfer unit 102. The gate of the charge transfer unit 102 is connected to a transfer signal line TR1. The drain of the charge transfer unit 102 is connected to the source of the MOS transistor 112a, the gate of the MOS transistor 113a, and one end of the charge holding unit 111a. The other end of the charge holding unit 111a is grounded. The drains of the MOS transistors 112a and 113a are commonly connected to a power supply line Vdd, and the source of the MOS transistor 113a is connected to the drain of the MOS transistor 114a. The source of the MOS transistor 114a is connected to an output signal line OUT1. The gates of the MOS transistors 112a and 114a are connected to a reset signal line RST1 and a selection signal line SEL1, respectively.

The charge transfer unit 102 is a transistor that transfers the charges generated by photoelectric conversion of the photoelectric conversion unit 101 to the charge holding unit 111a as described above. Transfer of charges in the charge transfer unit 102 is controlled by a signal transmitted through the transfer signal line TR1. The charge holding unit 111a is a capacitor for holding the charges transferred by the charge transfer unit 102. The MOS transistor 113a is a transistor for generating a signal based on the charges held in the charge holding unit 111a. The MOS transistor 114a is a transistor for outputting the signal generated by the MOS transistor 113a as an image signal to the output signal line OUT1. The MOS transistor 114a is controlled by a signal transmitted through the selection signal line SEL1.

The MOS transistor 112a is a transistor that resets the charge holding unit 111a by discharging the charges held in the charge holding unit 111a to the power supply line Vdd. Resetting by the MOS transistor 112a is controlled by a signal transmitted through the reset signal line RST1, and is performed prior to the transfer of the charges by the charge transfer unit 102. Note that, at the time of such resetting, the charge transfer unit 102 is made conductive, so that the photoelectric conversion unit 101 can be reset. In this manner, the image signal generation circuit 110a converts the charges generated by the photoelectric conversion unit 101 into an image signal.

Next, a circuit including the photoelectric conversion unit 103, the charge transfer unit 104, and the image signal generation circuit 110b will be described.

The photoelectric conversion unit 103 generates charges corresponding to applied light similarly to the photoelectric conversion unit 101. A photodiode may be used for the photoelectric conversion unit 103. As will be described later, the photoelectric conversion unit 103 performs photoelectric conversion of light having a different wavelength from that of the photoelectric conversion unit 101.

The charge transfer unit 104 transfers the charges generated by the photoelectric conversion unit 103 similarly to the charge transfer unit 102 and can be formed of an n-channel MOS transistor.

The image signal generation circuit 110b is configured as a circuit similar to the image signal generation circuit 110a, and is a circuit for generating image signals on the basis of the charges transferred by the charge transfer unit 104. The character added to the reference symbol of the MOS transistors of the image signal generation circuit 110b is changed from “a” to “b” to be distinguished.

A transfer signal line TR2, a reset signal line RST2, a selection signal line SEL2, and an output signal line OUT2 are connected to the gate of the charge transfer unit 104, the gate of the MOS transistor 112b, the gate of the MOS transistor 114b, and the source of the MOS transistor 114b, respectively. For the other components, the circuit configuration is the same as that of the photoelectric conversion unit 101, the charge transfer unit 102, and the image signal generation circuit 110a, and thus description thereof will be omitted.

Next, a circuit including the photoelectric conversion unit 105, the charge transfer unit 106, and the image signal generation circuit 110c will be described.

The photoelectric conversion unit 105 is a photoelectric conversion unit in which a photoelectric conversion film is configured to be sandwiched between a first electrode and a second electrode. In the figure, the photoelectric conversion unit 105 is configured to be a two-terminal element and generates charges based on the photoelectric conversion. As will be described later, the photoelectric conversion unit 105 performs photoelectric conversion of light having a different wavelength from those of the photoelectric conversion units 101 and 103. Further, the charge transfer unit 106 is an element for transferring the charges generated by the photoelectric conversion unit 105 similarly to the charge transfer unit 102. The charge transfer unit 106 is configured to be a three-terminal element, and includes an input terminal, an output terminal, and a control signal terminal. Similarly to the MOS transistor constituting the charge transfer unit 102, the input terminal and the output terminal are made conductive therebetween when the control signal is input to the control signal terminal. As will be described later, the photoelectric conversion unit 105 and the charge transfer unit 106 are integrally configured in the pixel 100. In the figure, the photoelectric conversion unit 105 and the charge transfer unit 106 are illustrated individually for the purpose of convenience.

Further, a power supply line Vou is further disposed in the pixel 100 of the figure. The power supply line Vou is a power supply line for supplying a bias voltage to the photoelectric conversion unit 105.

The image signal generation circuit 110c is configured as a circuit similar to the image signal generation circuit 110a, and is a circuit for generating image signals on the basis of the charges transferred by the charge transfer unit 106. The character added to the reference symbol of the MOS transistors of the image signal generation circuit 110c is changed from “a” to “c” to be distinguished.

A second electrode of the photoelectric conversion unit 105 is connected to the power supply line Vou, and a first electrode thereof is connected to the input terminal of the charge transfer unit 106. The control signal terminal of the charge transfer unit 106 is connected to a transfer signal line TR3, and the output terminal thereof is connected to the source of the MOS transistor 112c, the gate of the MOS transistor 113c, and one end of the charge holding unit 111c. A reset signal line RST3, a selection signal line SEL3, and an output signal line OUT3 are connected to the gate of the MOS transistor 112c, the gate of the MOS transistor 114c, and the source of the MOS transistor 114c, respectively. For the other components, the circuit configuration is the same as that of the photoelectric conversion unit 101, the charge transfer unit 102, and the image signal generation circuit 110a, and thus description thereof will be omitted.

Note that the transfer signal lines TR1 to 3, the reset signal lines RST1 to 3, and the selection signal lines SEL1 to 3 constitute the signal line 11. The output signal lines OUT1 to 3 constitute the signal line 12.

In such a manner, the circuits of the three systems are disposed in the pixel 100. In other words, the photoelectric conversion unit 101, the charge transfer unit 102, and the image signal generation circuit 110a, the photoelectric conversion unit 103, the charge transfer unit 104, and the image signal generation circuit 110b, and the photoelectric conversion unit 105, the charge transfer unit 106, and the image signal generation circuit 110c are disposed in the pixel 100. A series of operations of exposure (photoelectric conversion) by the photoelectric conversion unit 101 and the like, resetting of the charge holding unit 111a and the like, transfer of charges by the charge transfer unit 102 and the like, and output of image signals are sequentially executed in the circuits of three systems at different timings. Thus, the image signals of the incident light of three different wavelengths can be generated by one pixel 100. Such a method of generating the image signals is referred to as a line exposure sequential reading (rolling shutter) method.

[Configuration of Pixel]

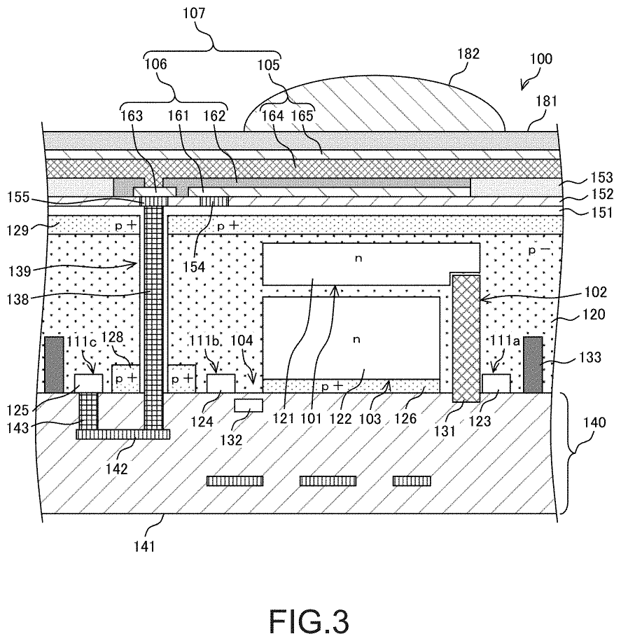

FIG. 3 is a cross-sectional diagram showing a configuration example of a pixel according to a first embodiment of the present disclosure. The figure is a schematic cross-sectional diagram showing a configuration example of a pixel 100. The pixel 100 of the figure includes a semiconductor substrate 120, a wiring region 140, an insulating film 151, insulating layers 152 and 153, a separation region 133, wiring layers 154 and 155, a photoelectric conversion unit 107, a through-electrode 138, a protective film 181, and an on-chip lens 182. Further, in the semiconductor substrate 120, a back-side high impurity concentration region 129 and a front-side high impurity concentration region 128 are disposed.

The semiconductor substrate 120 is a semiconductor substrate in which a diffusion region or the like of elements such as the photoelectric conversion units 101 and 103 and the image signal generation circuit 110a of the pixel 100 is formed. The semiconductor substrate 120 can be formed of, for example, silicon (Si). The diffusion region of the elements such as the photoelectric conversion unit 101 and the image signal generation circuit 110a is disposed in a well region formed in the semiconductor substrate 120. For the purpose of convenience, the semiconductor substrate 120 in the figure is assumed to include a p-type well region. When an n-type semiconductor region is disposed in the semiconductor substrate 120 serving as the p-type well region, it is possible to form the photoelectric conversion unit 101 and the like. A white rectangle inside the semiconductor substrate 120 represents the n-type semiconductor region. A wiring region 140 to be described later is formed on the front surface of the semiconductor substrate 120. Note that the front surface of the semiconductor substrate 120 represents the surface on the front side of the semiconductor substrate 120. On the other hand, the back surface of the semiconductor substrate 120 is the surface different from this front surface, representing the surface on the back side of the semiconductor substrate 120.

The photoelectric conversion unit 101 is constituted by an n-type semiconductor region 121. Specifically, the photodiode constituted by pn junction of the interface between the n-type semiconductor region 121 and the surrounding p-type well region corresponds to the photoelectric conversion unit 101. When incident light is applied, photoelectric conversion is caused in the n-type semiconductor region 121. Electrons among the charges generated by the photoelectric conversion are accumulated in the n-type semiconductor region 121. The n-type semiconductor region 121 is disposed in the vicinity of the back surface of the semiconductor substrate 120 and is disposed in a relatively shallow region of the semiconductor substrate 120 with respect to the surface irradiated with incident light. In such a relatively shallow region of the semiconductor substrate 120, light having a relatively short wavelength such as blue light is absorbed and photoelectrically converted. Therefore, the photoelectric conversion unit 101 performs photoelectric conversion of blue light of the incident light, and the image signal generation circuit 110a generates an image signal corresponding to the blue light.

The photoelectric conversion unit 103 is constituted by an n-type semiconductor region 122. Specifically, the photodiode constituted by pn junction of the interface between the n-type semiconductor region 122 and the surrounding p-type well region corresponds to the photoelectric conversion unit 103. The n-type semiconductor region 122 is disposed in the vicinity of the front surface of the semiconductor substrate 120 and is disposed in a relatively deep region of the semiconductor substrate 120 with respect to the surface irradiated with incident light. In such a relatively deep region of the semiconductor substrate 120, light having a relatively long wavelength such as red light is absorbed and photoelectrically converted. Therefore, the photoelectric conversion unit 103 performs photoelectric conversion of red light of the incident light, and the image signal generation circuit 110b generates an image signal corresponding to the red light. Note that the image sensor 1 for performing photoelectric conversion of the incident light applied to the back surface is referred to as a back-illuminated image sensor.

A semiconductor region 126 is disposed on the front surface side of the semiconductor substrate 120 adjacent to the n-type semiconductor region 122. The semiconductor region 126 is a semiconductor region configured to have a p-type high impurity concentration, for pinning the interface state of the front surface of the semiconductor substrate 120 in the vicinity of the photoelectric conversion unit 103. When the semiconductor region 126 is disposed, it is possible to reduce the dark current due to the interface state.

On the front surface side of the semiconductor substrate 120, n-type semiconductor regions 123 to 125 are formed. Those semiconductor regions constitute the charge holding portions 111a, 111b, and 111c described with reference to FIG. 2. The semiconductor region constituting the charge holding portion 111a or the like is referred to as a floating diffusion (FD) region.

A gate electrode 131 is configured in a shape in which an electrode is embedded through a gate insulating film in a hole formed in the semiconductor substrate 120, and is disposed in the vicinity of the n-type semiconductor regions 121 and 123. The gate electrode 131 and the n-type semiconductor regions 121 and 123 constitute a MOS transistor. When a gate voltage is applied to the gate electrode 131, a channel is formed in the well region in the vicinity of the gate electrode 131, and the n-type semiconductor regions 121 and 123 become conductive. As a result, charges accumulated in the n-type semiconductor region 121 of the photoelectric conversion unit 101 are transferred to the n-type semiconductor region 123 constituting the charge holding unit 111a. Thus, the transistor for transferring charges in a direction perpendicular to the semiconductor substrate 120 is referred to as a vertical transistor. The vertical transistor constitutes the charge transfer unit 102. The gate insulating film can be formed of, for example, silicon oxide (SiO₂), silicon nitride (SiN), or a high dielectric film. The gate electrode 131 can be formed of, for example, metal or polysilicon.

Further, on the front surface of the semiconductor substrate 120, the gate electrode 132 is disposed through the gate insulating film. The gate electrode 132 and the n-type semiconductor regions 122 and 124 constitute a MOS transistor. Specifically, the n-type semiconductor regions 122 and 124 correspond to a source region and a drain region, respectively, and the p-type well region between the n-type semiconductor regions 122 and 124 corresponds to a channel region. When a control signal is applied to the gate electrode 132, a channel is formed, the n-type semiconductor regions 122 and 124 become conductive, and charges accumulated in the photoelectric conversion unit 103 are transferred to the charge holding portion 111b. Such a MOS transistor constitutes the charge transfer unit 104.

Note that the charges are transferred to the n-type semiconductor region 125 constituting the charge holding portion 111c via a through-electrode 138, a wiring layer 142, and a contact plug 143, which will be described later. Description on the elements other than those described above constituting the pixel 100 will be omitted.

The through-electrode 138 is an electrode configured to penetrate through the semiconductor substrate 120. The through-electrode 138 transfers the charges generated by the photoelectric conversion unit 107, which will be described later, to the charge holding unit 111c disposed on the front surface of the semiconductor substrate 120. The through-electrode 138 of the figure is disposed between wiring layers 155 and 142 to be described later. The through-electrode 138 can be configured by disposing a conductive material in a through-hole 139 formed from the back surface to the front surface of the semiconductor substrate 120. Further, an insulating film can be disposed between the wall surface of the through-hole 139 and the through-electrode 138. The through-hole 139 can be formed by performing dry etching on the semiconductor substrate 120, for example. After an insulating material serving as a material of the insulating film is disposed in the through-hole 139, a through-hole reaching the wiring layer 142 is formed again from the back surface of the semiconductor substrate 120, and a conductive material is embedded therein, so that the through-electrode 138 can be formed. A conductive material can be embedded by, for example, chemical vapor deposition (CDV).

For the conductive material forming the through-electrode 138, for example, an Si material doped with an impurity such as phosphorus doped amorphous silicon (PDAS), or a metal such as aluminum (Al), tungsten (W), titanium (Ti), or cobalt (Co) can be used.

Further, for the insulating material, inorganic materials such as SiO₂ and SiN can be used. It is also possible to use organic materials such as polymethyl methacrylate (PMMA), polyvinylphenol (PVP), polyvinyl alcohol (PVA), polyimide, polycarbonate (PC), polyethylene terephthalate (PET), and polystyrene. Further, it is also possible to use silanol derivatives such as N-(2-aminoethyl)-3-aminopropyltrimethoxysilane (AEAPTMS), 3-mercaptopropyltrimethoxysilane (MPTMS), and octadecyltrichlorosilane (OTS). Further, linear hydrocarbons having a functional group capable of bonding with an electrode at one end of a novolac type phenol resin, a fluorine-based resin, an octadecanethiol, a dodecyl isocyanate, or the like can also be used for an insulating material.

The front-side high impurity concentration region 128 and the back-side high impurity concentration region 129 are semiconductor regions disposed in regions adjacent to the through-electrode 138 of the semiconductor substrate 120 and are configured to have a high impurity concentration. The front-side high impurity concentration region 128 and the back-side high impurity concentration region 129 are formed in regions adjacent to the front surface and the back surface of the semiconductor substrate 120, respectively. The front-side high impurity concentration region 128 and the back-side high impurity concentration region 129 of the figure can be formed in a p-type structure having the same conductivity type as the well region.

Crystal defects are caused in the semiconductor substrate 120 in the vicinity of the through-electrode 138 by etching or the like of the semiconductor substrate 120 when the through-electrode 138 described above is formed. In particular, many crystal defects are formed in the front surface and the back surface of the semiconductor substrate 120. When charges (electrons) caused by the crystal defects flow into the n-type semiconductor region 121 or the like of the photoelectric conversion unit 101 or the like, a dark current is caused and noise is mixed into the image signal. For that reason, the front-side high impurity concentration region 128 and the back-side high impurity concentration region 129 are disposed. When the p-type, high impurity concentration semiconductor regions are disposed, the trap level due to the crystal defects can be pinned. Further, the electrons generated due to crystal defects disappear by recombination inside the front-side high impurity concentration region 128 and the back-side high impurity concentration region 129 where a large number of holes exist. As a result, the dark current caused by the through-electrode 138 can be reduced.

In addition, in a region between the front-side high impurity concentration region 128 and the back-side high impurity concentration region 129 in the vicinity of the through-electrode 138, a well region having the same impurity concentration as the region where the photoelectric conversion unit 101 and the like are disposed can be disposed. The photoelectric conversion unit 101 and the like can be brought close to the through-electrode 138, and the size of the photoelectric conversion unit 101 and the like can be increased. It is possible to improve the storage capacity for the charges generated by the photoelectric conversion.

The front-side high impurity concentration region 128 may have a shape surrounding the through-electrode 138 on the front surface of the semiconductor substrate 120. Further, the front-side high impurity concentration region 128 is suitably formed to have an impurity concentration of, for example, substantially 10¹⁷ cm⁻³ or more. This is because the influence of crystal defects can be reduced.

The back-side high impurity concentration region 129 can be formed in a shape surrounding the through-electrode 138 on the back surface of the semiconductor substrate 120. Note that the back-side high impurity concentration region 129 of the figure represents an example of being disposed also in the well region where the photoelectric conversion unit 101 or the like is disposed. When the back-side high impurity concentration region 129 is disposed on the back surface of the semiconductor substrate 120 in the vicinity of the photoelectric conversion unit 101 or the like, it is possible to reduce the dark current due to the interface state of the back surface of the semiconductor substrate 120. Further, the back-side high impurity concentration region 129 is suitably formed to have an impurity concentration of, for example, substantially 10¹⁸ cm⁻³ or more. This is because the influence of crystal defects can be reduced.

The separation region 133 is disposed at the boundary of the pixel 100 to separate the semiconductor substrate 120. The separation region 133 may be formed by a shallow trench isolation (STI). Note that since the front-side high impurity concentration region 128 is disposed in the pixel 100 of the figure, a separation region for separating the through-electrode 138, the photoelectric conversion unit 101, and the like can be omitted.

The wiring region 140 is a region disposed adjacent to the front surface of the semiconductor substrate 120, in which the wiring of the elements formed in the semiconductor substrate 120 is formed. An insulating layer 141 and a wiring layer 142 are disposed in the wiring region 140. The wiring layer 142 is wiring formed of metal such as copper (Cu), for transmitting a signal to an element or the like formed in the semiconductor substrate 120. The insulating layer 141 is for insulating the wiring layer 142. The insulating layer 141 can be formed of, for example, SiO₂. Further, the insulating layer 141 and the wiring layer 142 can be formed in multiple layers. Note that in the figure the insulating layer 141 between the gate electrode 132 and the semiconductor substrate 120 is referred to as a gate oxide film. Further, the wiring layer 142 and the n-type semiconductor region 125 are connected by a contact plug 143.

The insulating film 151 is a film for insulating the back surface of the semiconductor substrate 120. The insulating film 151 can be formed of SiO₂ or SiN.

The wiring layers 154 and 155 are wiring layers disposed on the back surface of the semiconductor substrate 120. The wiring layer 154 is wiring connected to a charge accumulation electrode 161 to be described later. Further, the wiring layer 155 is wiring for connecting a first electrode 163, which will be described later, and the through-electrode 138 to each other. The insulating layer 152 insulates the wiring layers 154 and 155.

The photoelectric conversion unit 107 is a photoelectric conversion unit disposed adjacent to the back surface of the semiconductor substrate 120. The photoelectric conversion unit 107 of the figure is disposed on the back surface of the semiconductor substrate 120 via the insulating layer 152 and the insulating film 151. The photoelectric conversion unit 107 includes a first electrode 163, an insulating film 162, a photoelectric conversion film 164, a second electrode 165, and the charge accumulation electrode 161. The photoelectric conversion unit 107 is configured by stacking the charge accumulation electrode 161, the insulating film 162, the photoelectric conversion film 164, and the second electrode 165. The photoelectric conversion film 164 and the second electrode 165 are commonly disposed in the plurality of pixels 100 or the like, and the first electrode 163, the charge accumulation electrode 161, and the insulating film 162 are individually disposed in the pixels 100 or the like. An insulating layer 153 is disposed around the charge accumulation electrode 161 and the insulating film 162.

The photoelectric conversion film 164 is a film formed of an organic photoelectric conversion film and performs photoelectric conversion of incident light. Such a photoelectric conversion film 164 can be formed of an organic photoelectric conversion material containing, for example, a rhodamine-based dye, a melacyanine-based dye, quinacridone, a phthalocyanine-based dye, a coumarin-based dye, and tris-8-hydroxyquinoline Al. In addition, the photoelectric conversion film 164 can be configured to perform photoelectric conversion by absorbing light of a specific wavelength of incident light. In the pixel 100 of the figure, it can be configured to perform photoelectric conversion of green light. When the photoelectric conversion film 164 is stacked on the semiconductor substrate 120 including the photoelectric conversion unit 101 for performing photoelectric conversion of blue light and the photoelectric conversion unit 103 for performing photoelectric conversion of red light described above, it is possible to generate image signals respectively corresponding to the three wavelengths in one pixel 100.

The second electrode 165 is an electrode disposed adjacent to the photoelectric conversion film 164. The second electrode 165 may be formed of, for example, indium-tin-oxide (ITO). The insulating film 162 is a film that insulates the photoelectric conversion film 164 and the charge accumulation electrode 161 from each other. The insulating film 162 can be formed of, for example, SiO₂. The charge accumulation electrode 161 is an electrode that is stacked on the photoelectric conversion film 164 via the insulating film 162 and applies a voltage to the photoelectric conversion film 164. The charge accumulation electrode 161 can be formed of, for example, ITO. The first electrode 163 is an electrode to which charges generated by the photoelectric conversion film 164 are output.

Note that the second electrode 165 and the photoelectric conversion film 164 correspond to the photoelectric conversion unit 105 described with reference to FIG. 2. The insulating film 162, the charge accumulation electrode 161, and the first electrode 163 correspond to the charge transfer unit 106 described with reference to FIG. 2.

Further, the second electrode 165 corresponds to a terminal connected to the power supply line Vou (not shown) described with reference to FIG. 2. Further, the first electrode 163 corresponds to the output terminal of the charge transfer unit 106 in FIG. 2. Further, the charge accumulation electrode 161 corresponds to the control signal terminal of the charge transfer unit 106.

During the exposure period of the image sensor, a control signal of a voltage higher than the voltage of the power supply line Vou is applied to the charge accumulation electrode 161. As a result, electrons in the charges generated by the photoelectric conversion of the photoelectric conversion film 164 are attracted to the charge accumulation electrode 161, and are accumulated in the region of the photoelectric conversion film 164 in the vicinity of the charge accumulation electrode 161 via the insulating film 162. Subsequently, when the charges generated by the photoelectric conversion are transferred, a control signal of a voltage lower than the voltage of the power supply line Vou is applied to the charge accumulation electrode 161. Thus, the charges (electrons) accumulated in the photoelectric conversion film 164 move to the first electrode 163, and are transferred to the n-type semiconductor region 125 of the charge holding portion 111c via the through-electrode 138 and the like.

The protective film 181 is a film for protecting the back surface of the semiconductor substrate 120 on which the photoelectric conversion unit 107 is disposed. The protective film 181 can be formed of, for example, SiO₂ or SiN.

The on-chip lens 182 is a lens for condensing incident light. The on-chip lens 182 is configured in a hemispherical shape, and condenses incident light to the photoelectric conversion unit 101 or the like. The on-chip lens 182 may be formed of, for example, an organic material such as acrylic resin or an inorganic material such as SiN.

[Method of Producing Image Sensor]

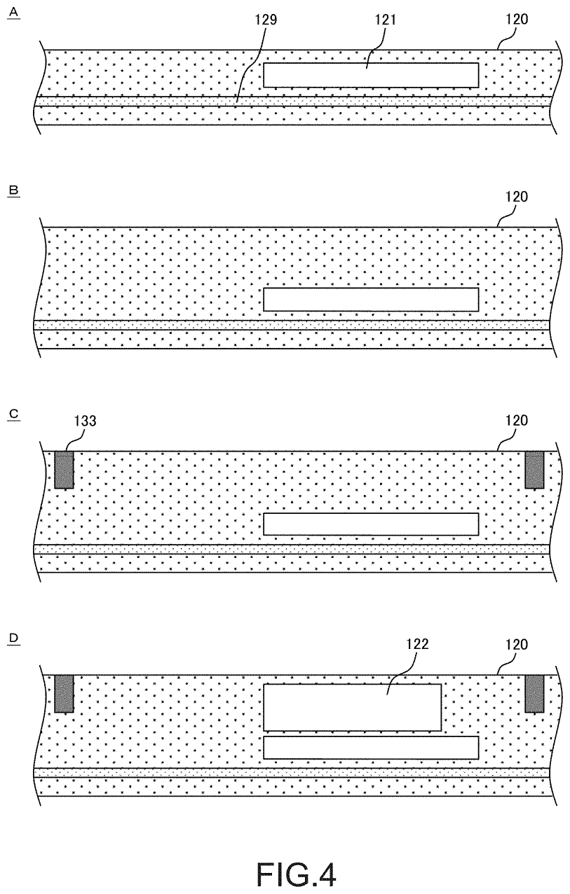

FIGS. 4 to 6 are diagrams showing an example of a method of producing an image sensor according to the first embodiment of the present disclosure. FIGS. 4 to 6 are diagrams showing an example of a production process of the image sensor 1. First, a back-side high impurity concentration region 129 is formed at the deep portion of the semiconductor substrate 120. Next, the semiconductor region 121 is formed above the back-side high impurity concentration region 129. These can be performed by, for example, ion implantation (A in FIG. 4.

Next, a semiconductor film by epitaxial growth is formed on the semiconductor substrate 120 (B in FIG. 4). Next, a separation region 133 is formed in the front surface of the semiconductor substrate 120 (C in FIG. 4). This can be formed by, for example, forming a groove in the front surface of the semiconductor substrate 120 and disposing an insulating material in the groove.

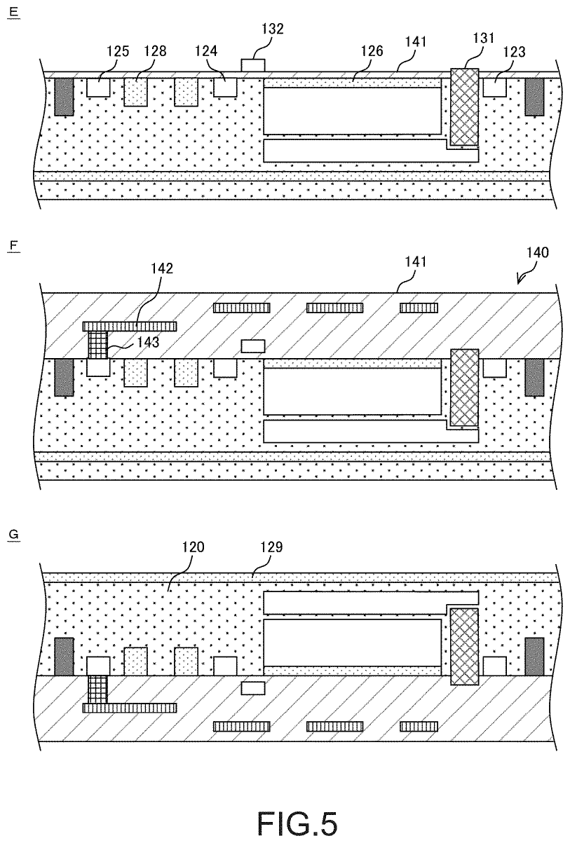

Next, a well region is formed in the semiconductor substrate 120 to form a semiconductor region 122. These can be performed by, for example, ion implantation (D in FIG. 4). Next, semiconductor regions 123 to 125 and a front-side high impurity concentration region 128 are formed. This can be performed by, for example, ion implantation. Next, a gate oxide film and gate electrodes 131 and 132 are formed. Note that a semiconductor region 124 can also be formed by self-alignment by performing ion implantation after forming the gate electrode 132 (E in FIG. 5).

Next, a contact plug 143, a wiring layer 142, and an insulating layer 141 are disposed to form a wiring region 140 (F in FIG. 5).

Next, the semiconductor substrate 120 is turned upside down, and the back surface of the semiconductor substrate 120 is grinded to reduce the thickness. This can be performed by, for example, chemical mechanical polishing (CMP) (G in FIG. 5).

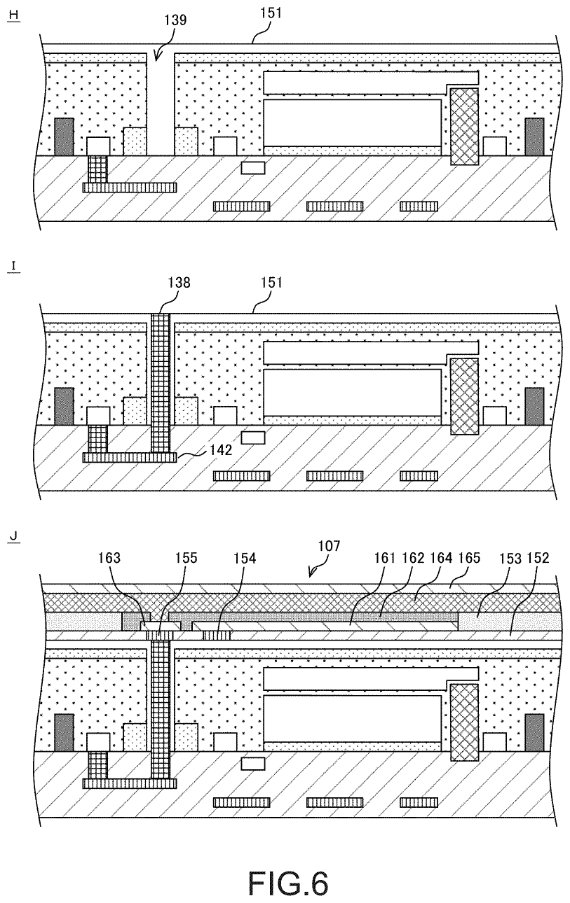

Next, a through-hole 139 is formed in a region, of the back surface of the semiconductor substrate 120, in which a through-electrode 138 is to be disposed. This can be performed by, for example, dry etching. Next, an insulating film 151 is disposed on the back surface of the semiconductor substrate 120, and an insulating material is embedded in the through-hole 139 (H in FIG. 6).

Next, the through-electrode 138 is formed. This can be formed by, for example, forming a through-hole again in the insulating material embedded in the through-hole 139 and embedding the metal material therein. At this time, a through-hole is formed also in the insulating layer 141 of the region reaching the wiring layer 142, and thus it is possible to connect the through-electrode 138 to the wiring layer 142 (I in FIG. 6).

Next, wiring layers 154 and 155 and an insulating layer 152 are disposed. Next, a first electrode 163 and a charge accumulation electrode 161 are disposed, and an insulating film 162 is disposed. Next, an insulating layer 153 is disposed. An opening is formed in the insulating film 162 adjacent to the first electrode 163, and a photoelectric conversion film 164 and a second electrode 165 are stacked in this order. Thus, the photoelectric conversion unit 107 can be formed (J in FIG. 6). Subsequently, a protective film 181 and an on-chip lens 182 are disposed, so that an image sensor 1 can be produced.

As described above, in the image sensor 1 according to the first embodiment of the present disclosure, the front-side high impurity concentration region 128 and the back-side high impurity concentration region 129 are respectively disposed on the front surface and the back surface of the semiconductor substrate 120 in the vicinity of the through-electrode 138. Thus, it is possible to reduce the noise by reducing the dark current caused by the through-electrode 138, and to prevent the image quality from being deteriorated.

### 2. Secondary Embodiment

In the image sensor 1 of the first embodiment described above, the front-side high impurity concentration region 128 and the back-side high impurity concentration region 129 are disposed on the semiconductor substrate 120. On the other hand, an image sensor 1 of a second embodiment of the present disclosure proposes shapes of the front-side high impurity concentration region 128 and the back-side high impurity concentration region 129.

[Configurations of Front-Side High Impurity Concentration Region and Back-Side High Impurity Concentration Region]

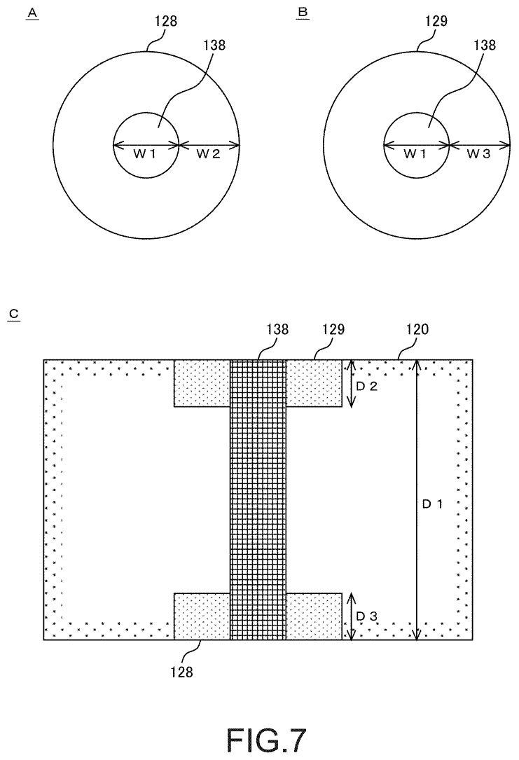

FIG. 7 is a diagram showing configuration examples of a front-side high impurity concentration region and a back-side high impurity concentration region according to the second embodiment of the present disclosure. A of the figure is a plan view showing a configuration example of a front-side high impurity concentration region 128. In A of the figure, the circular region of the central portion represents a through-electrode 138, and the outer circular region represents the front-side high impurity concentration region 128. Further, in A of the figure, W1 represents the diameter of the through-electrode 138, and W2 represents the size of the front-side high impurity concentration region 128. Specifically, W2 represents a width between an end portion adjacent to the through-electrode 138 and an outer end portion of the front-side high impurity concentration region 128. As indicated in A of the figure, W2 can be configured to have a size equal to or larger than W1. When the through-electrode 138 is formed, many crystal defects are formed in a region having substantially the same size as the outer diameter of the through-electrode 138 around the through-electrode 138 on the front surface of the semiconductor substrate 120. Therefore, the size of the front-side high impurity concentration region 128 is configured to be equal to or larger than the size of the region in which the crystal defects are formed, and thus the influence of the crystal defects can be reduced.

In addition, B of the figure is a plan view showing a configuration example of a back-side high impurity concentration region 129. In B of the figure, the circular region of the central portion represents the through-electrode 138, and the outer circular region represents the back-side high impurity concentration region 129. Further, W3 represents the size of the back-side high impurity concentration region 129. Similarly to W2, W3 can also be configured to have a size equal or larger than W1. When the through-electrode 138 is formed, many crystal defects are formed in a region having substantially the same size as the outer diameter of the through-electrode 138 around the through-electrode 138 also on the back surface of the semiconductor substrate 120. The size of the back-side high impurity concentration region 129 is configured to be equal to or larger than the size of the region in which the crystal defects are formed, and thus the influence of the crystal defects can be reduced.

As described above, the front-side high impurity concentration region 128 is formed in a cylindrical shape to surround the through-electrode 138 and have a width equal to or larger than the diameter of the through-electrode 138, so that the influence of crystal defects can be reduced. Similarly, the back-side high impurity concentration region 129 is formed in a cylindrical shape to surround the through-electrode 138 and have a width equal to or larger than the diameter of the through-electrode 138, so that the influence of crystal defects can be reduced.

Further, C of the figure is a cross-sectional diagram showing a configuration example of the front-side high impurity concentration region 128 and the back-side high impurity concentration region 129. C of the figure is a schematic cross-sectional diagram of the semiconductor substrate 120 in the vicinity of the front-side high impurity concentration region 128 and the back-side high impurity concentration region 129. In C of the figure, D1 represents the thickness of the semiconductor substrate 120. Further, D2 and D3 represent the thickness of the back-side high impurity concentration region 129 and the thickness of the front-side high impurity concentration region 128, respectively. D2 and D3 can be configured to have a thickness of substantially ⅙ of the thickness D1 of the semiconductor substrate 120. As described above, many crystal defects are formed in the vicinity of the back surface and the front surface of the semiconductor substrate 120. Many crystal defects are formed in a range of ⅙ of the thickness of the semiconductor substrate 120 from the back surface and the front surface of the semiconductor substrate 120. Therefore, the back-side high impurity concentration region 129 and the front-side high impurity concentration region 128 are disposed in this region, so that the influence of the dark current can be reduced.

The size and depth of the back-side high impurity concentration region 129 and the front-side high impurity concentration region 128 in plan view are defined, and thus it is possible to ensure a region in which the photoelectric conversion unit 101 and the like are disposed while reducing the dark current.

Since the other configurations of the image sensor 1 are the same as those of the image sensor 1 described in the first embodiment of the present disclosure, description thereof is omitted.

As described above, in the image sensor 1 according to the second embodiment of the present disclosure, the sizes and the like of the back-side high impurity concentration region 129 and the front-side high impurity concentration region 128 are defined, and thus it is possible to ensure a region for the photoelectric conversion unit 101 and the like while reducing the dark current.

### 3. Third Embodiment

In the image sensor 1 of the first embodiment described above, the central portion of the semiconductor substrate 120 in the vicinity of the through-electrode 138 is configured to have the same impurity concentration as that of the well region. On the other hand, an image sensor 1 of a third embodiment of the present disclosure is different from the first embodiment described above in that the central portion of the semiconductor substrate 120 in the vicinity of the through-electrode 138 is configured to have an impurity concentration different from that of the well region.

[Configuration of Pixel]

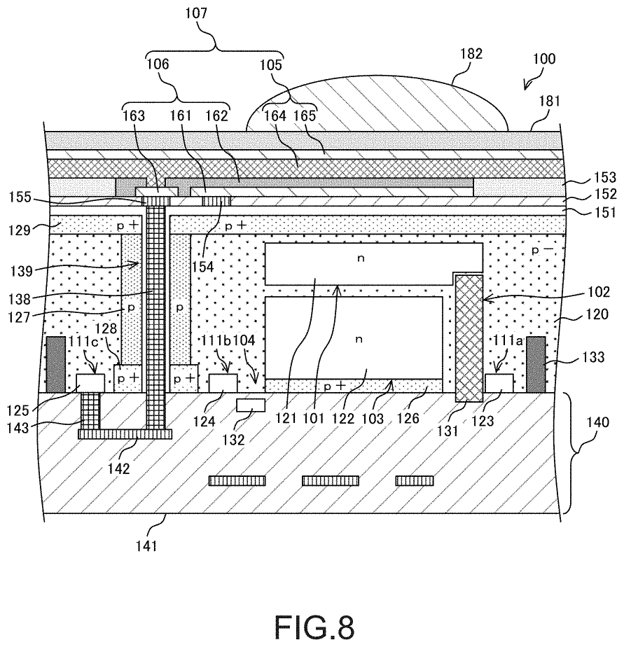

FIG. 8 is a cross-sectional diagram showing a configuration example of a pixel according to the third embodiment of the present disclosure. The figure is a schematic cross-sectional diagram showing a configuration example of a pixel 100, similarly to FIG. 3. The pixel 100 is different from the pixel 100 of FIG. 3 in that a semiconductor region 127 is further disposed in the vicinity of the through-electrode 138.

The semiconductor region 127 is a semiconductor region adjacent to the through-electrode 138 between the front-side high impurity concentration region 128 and the back-side high impurity concentration region 129 of the semiconductor substrate 120. The semiconductor region 127 can be formed into a p-type region having the same conductivity type as that of the front-side high impurity concentration region 128 and the back-side high impurity concentration region 129, and formed to have an impurity concentration lower than that of the front-side high impurity concentration region 128 and the back-side high impurity concentration region 129 and higher than that of the well region. For example, the semiconductor region 127 can be configured to have an impurity concentration of 10¹⁶ cm⁻³ or more. In such a manner, the impurity concentration of the region adjacent to the through-electrode 138 between the front-side high impurity concentration region 128 and the back-side high impurity concentration region 129 of the semiconductor substrate 120 is adjusted, so that the influence of the dark current in such a region can be reduced.

On the other hand, the impurity concentration of the region between the front-side high impurity concentration region 128 and the back-side high impurity concentration region 129 of the semiconductor substrate 120 is configured to have an impurity concentration lower than that of the front-side high impurity concentration region 128 or the like, so that it is possible to reduce the region to be doped with an impurity at a high concentration, and to simplify the production process of the image sensor 1.

Since the other configurations of the image sensor 1 are the same as those of the image sensor 1 described in the first embodiment of the present disclosure, description thereof is omitted.

As described above, in the image sensor 1 according to the third embodiment of the present disclosure, the impurity concentration of the region adjacent to the through-electrode 138 between the front-side high impurity concentration region 128 and the back-side high impurity concentration region 129 of the semiconductor substrate 120 is adjusted. As a result, it is possible to further reduce the influence of the dark current while simplifying the production process of the image sensor 1.

### 4. Fourth Embodiment

In the image sensor 1 of the first embodiment described above, the photoelectric conversion units 101 and 103 are disposed on the semiconductor substrate 120. On the other hand, an image sensor 1 of a fourth embodiment of the present disclosure is different from the first embodiment described above in that the photoelectric conversion units 101 and 103 of the semiconductor substrate 120 are omitted.

[Configuration of Pixel]

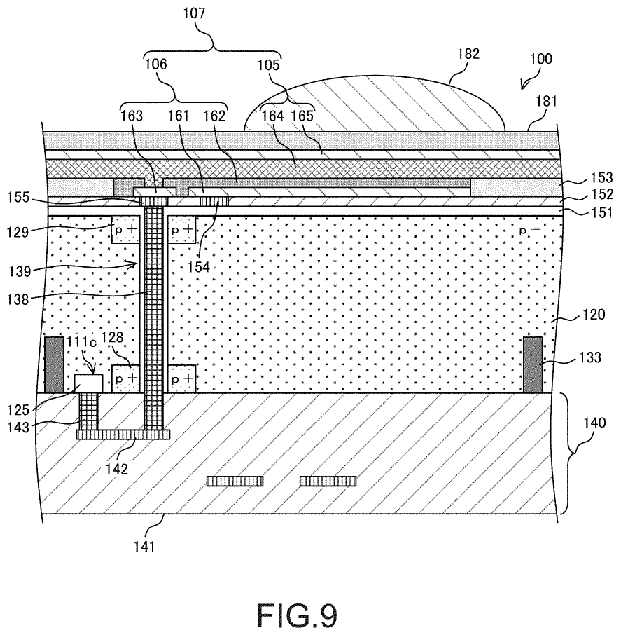

FIG. 9 is a cross-sectional diagram showing a configuration example of a pixel according to the fourth embodiment of the present disclosure. The figure is a schematic cross-sectional diagram showing a configuration example of a pixel 100, similar to FIG. 3. The pixel 100 is different from the pixel 100 of FIG. 3 in that the photoelectric conversion units 101 and 107, the charge transfer units 102 and 104, and the semiconductor region 126 are omitted.

The pixel 100 in the figure is a pixel that generates a monochrome image signal and includes a photoelectric conversion unit 107. Specifically, such a pixel 100 corresponds to a pixel constituted by a circuit in which the photoelectric conversion units 101 and 103, the charge transfer units 102 and 104, and the image signal generation circuits 110a and 110b are omitted in the circuit diagram of FIG. 2.

The charges generated by the photoelectric conversion of the photoelectric conversion unit 107 in the figure are transmitted to the charge holding unit 111c on the front surface of the semiconductor substrate 120 via the through-electrode 138, and an image signal is generated by an image signal generation circuit 110c (not shown). Also in the pixel 100 in the figure, a front-side high impurity concentration region 128 and a back-side high impurity concentration region 129 are disposed, and the dark current caused by the through-electrode 138 can be reduced. Note that the back-side high impurity concentration region 129 in the figure represents an example configured in the same shape as the front-side high impurity concentration region 128.

Since the other configurations of the image sensor 1 are the same as those of the image sensor 1 described in the first embodiment of the present disclosure, description thereof is omitted.

As described above, the image sensor 1 of the fourth embodiment of the present disclosure includes the front-side high impurity concentration region 128 and the back-side high impurity concentration region 129 in the pixel 100 in which the photoelectric conversion unit 101 and the like of the semiconductor substrate 120 are omitted. This makes it possible to reduce the influence of the dark current.

### 5. Application Example to Camera

The technology according to the present disclosure (the present technology) is applicable to a variety of products. For example, the present technology may be realized as an image sensor mounted on an imaging apparatus such as a camera.

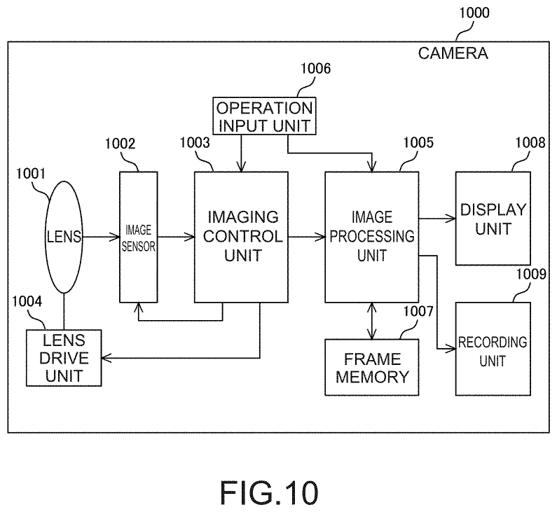

FIG. 10 is a block diagram showing a schematic configuration example of a camera that is an example of an imaging apparatus to which the present technology can be applied. A camera 1000 includes a lens 1001, an image sensor 1002, an imaging control unit 1003, a lens drive unit 1004, an image processing unit 1005, an operation input unit 1006, a frame memory 1007, a display unit 1008, and a recording unit 1009.

The lens 1001 is an imaging lens of the camera 1000. This lens 1001 collects light from a subject and causes the collected light to enter the image sensor 1002 described below to form an image of the subject.

The image sensor 1002 is a semiconductor device that images the light from a subject collected by the lens 1001. This image sensor 1002 generates an analog image signal corresponding to the applied light, converts the analog image signal into a digital image signal, and outputs the digital image signal.

The imaging control unit 1003 controls imaging in the image sensor 1002. This imaging control unit 1003 controls the image sensor 1002 by generating a control signal and outputting the control signal to the image sensor 1002. Further, the imaging control unit 1003 is capable of performing autofocusing in the camera 1000 on the basis of the image signal output from the image sensor 1002. Here, the autofocusing is a system that detects a focal position of the lens 1001 and automatically adjusts the focal position. As this autofocusing, a method of detecting the focal position by detecting the image plane phase difference by the phase difference pixel disposed in the image sensor 1002 (image plane phase difference autofocus) can be used. Further, a method of detecting, as the focal position, a position at which an image exhibits the highest contrast (contrast autofocus) may be applied. The imaging control unit 1003 adjusts the position of the lens 1001 via the lens drive unit 1004 on the basis of the detected focal position to perform autofocusing. Note that the imaging control unit 1003 can include, for example, a DSP (Digital Signal Processor) on which firmware is mounted.

The lens drive unit 1004 drives the lens 1001 on the basis of the control of the imaging control unit 1003. This lens drive unit 1004 is capable of driving the lens 1001 by changing the position of the lens 1001 using a built-in motor.

The image processing unit 1005 processes the image signal generated by the image sensor 1002. For example, demosaicking for generating an image signal of an insufficient color among image signals corresponding to red, green, and blue for each pixel, noise reduction for removing noise from an image signal, encoding of an image signal, and the like correspond to this processing. The image processing unit 1005 can include, for example, a microcomputer on which firmware is mounted.

The operation input unit 1006 receives an operation input from a user of the camera 1000. As this operation input unit 1006, for example, a push button or a touch panel can be used. The operation input received by the operation input unit 1006 is transmitted to the imaging control unit 1003 and the image processing unit 1005. After that, the processing corresponding to the operation input, e.g., processing such as imaging a subject is started.

The frame memory 1007 is a memory for storing a frame that is an image signal for one screen. This frame memory 1007 is controlled by the image processing unit 1005, and maintains the frame during the image processing.

The display unit 1008 displays the image processed by the image processing unit 1005. As this display unit 1008, for example, a liquid crystal panel can be used.

The recording unit 1009 records the image processed by the image processing unit 1005. As this recording unit 1009, for example, a memory card or a hard disk can be used.

A camera to which the present disclosure can be applied has been described above. The present technology can be applied to the image sensor 1002 of the configurations described above. Specifically, the image sensor 1 described in FIG. 1 can be applied to the image sensor 1002. By applying the image sensor 1 to the image sensor 1002, it is possible to reduce the influence of a dark current, and prevent the image quality of the image generated by the camera 1000 from being deteriorated. Note that the image processing unit 1005 is an example of the processing circuit described in the claims. The camera 1000 is an example of the imaging apparatus described in the claims.

### 6. Application Example to Endoscopic Surgery System

The technology according to the present disclosure is applicable to a variety of products. For example, the technology according to the present disclosure may be applied to an endoscopic surgery system.

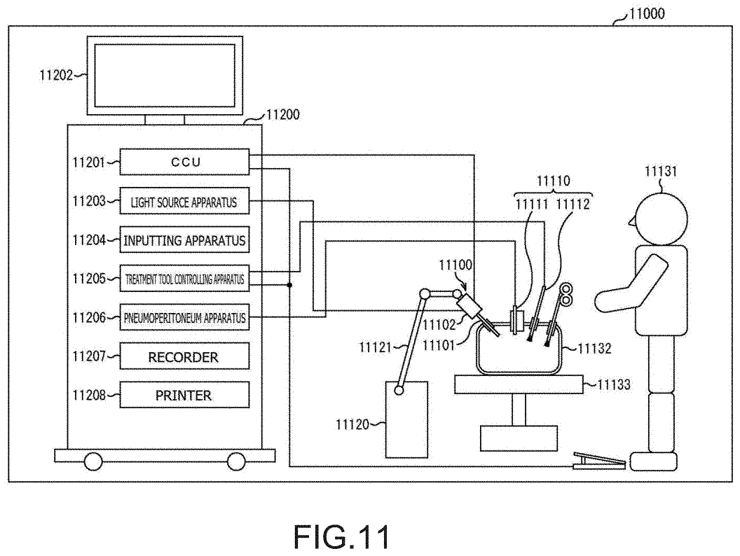

FIG. 11 is a view depicting an example of a schematic configuration of an endoscopic surgery system to which the technology according to an embodiment of the present disclosure (present technology) can be applied.

In FIG. 11, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

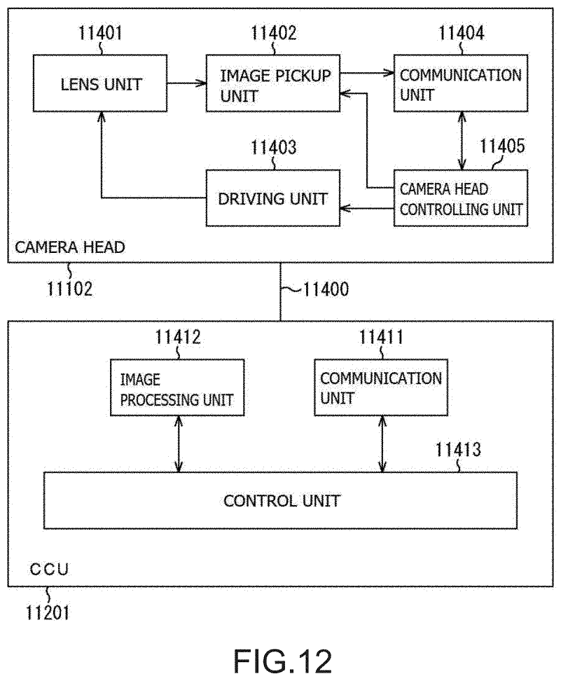

FIG. 12 is a block diagram depicting an example of a functional configuration of the camera head 11102 and the CCU 11201 depicted in FIG. 11.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to the image pickup unit 11402 among the configurations described above. Specifically, the image sensor 1 described in FIG. 1 can be applied to the image pickup unit 10402. By applying the technology according to the present disclosure to the image pickup unit 10402, it is possible to prevent the image quality of the image from deteriorating, so that a surgeon can reliably confirm a surgical region.

Note that the endoscopic surgery system has been described here as an example, but the technology according to the present disclosure may be applied to, for example, a microscopic surgery system.

### 7. Application Example to Mobile Body

The technology according to the present disclosure is applicable to a variety of products. For example, the technology according to the present disclosure may be achieved as an apparatus mounted on any type of mobile bodies such as an automobile, an electric car, a hybrid electric vehicle, a motorcycle, a bicycle, personal mobility, an airplane, a drone, a ship, and a robot.

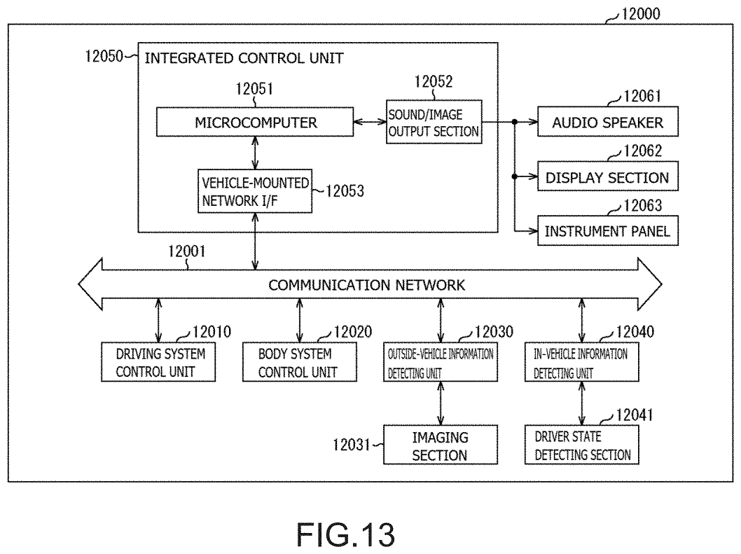

FIG. 13 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 13, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 13, an audio speaker 12061, a display section 12062, and an instrument panel 12063 are illustrated as the output device. The display section 12062 may, for example, include at least one of an on-board display and a head-up display.

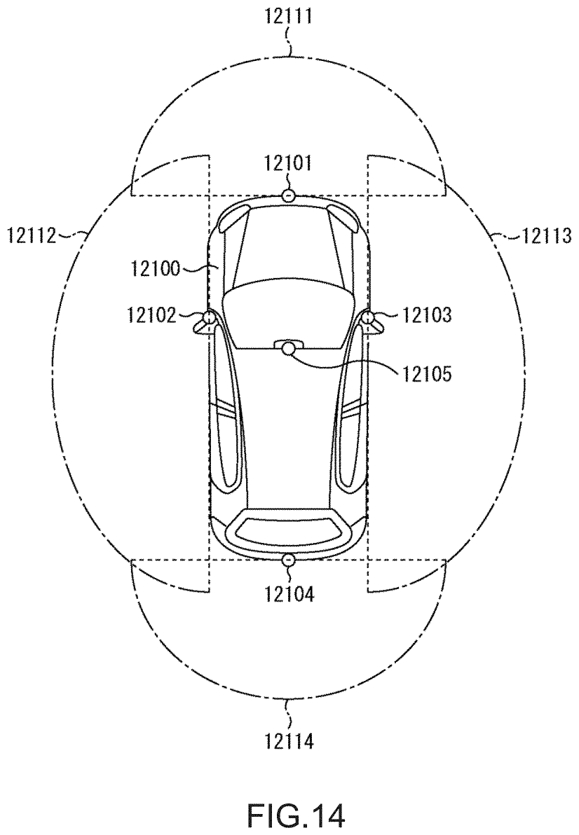

FIG. 14 is a diagram depicting an example of the installation position of the imaging section 12031.

In FIG. 14, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 14 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 and the like among the configurations described above. Specifically, the image sensor 1 described in FIG. 1 can be applied to the imaging section 12031. By applying the technology according to the present disclosure to the imaging section 12031, it is possible to prevent the image quality of the image from deteriorating, and to obtain a more visible captured image. It is possible to reduce fatigue of the driver.

Finally, the description of the above-mentioned embodiments is an example of the present disclosure, and the present disclosure is not limited to the above-mentioned embodiments. Therefore, it goes without saying that various modifications can be made depending on the design and the like without departing from the technical idea according to the present disclosure even in the case of an embodiment other than the above-mentioned embodiments.

In addition, the effects described herein are merely illustrative and not restrictive. Further, there may be other effects.

Further, the drawings in the above-mentioned embodiments are schematic, and the ratio of the dimensions of the respective units and the like do not necessarily coincide with real ones. Further, it goes without saying that the drawings have different dimensional relationships and different ratios of dimensions with respect to the same portion.

Note that the present technology may also take the following configurations.

(1) An image sensor, including:

a photoelectric conversion unit that is disposed on a back surface of a semiconductor substrate and performs photoelectric conversion of incident light;

a through-electrode that is formed in a shape penetrating from the back surface to a front surface of the semiconductor substrate and transmits a charge generated by the photoelectric conversion;

a charge holding unit that is disposed on the front surface of the semiconductor substrate and holds the transmitted charge;

a back-side high impurity concentration region that is disposed in a region adjacent to the through-electrode on the back surface of the semiconductor substrate and is formed to have a higher impurity concentration than an impurity concentration of a region adjacent to the through-electrode at the central portion of the semiconductor substrate; and

a front-side high impurity concentration region that is disposed in a region adjacent to the through-electrode on the front surface of the semiconductor substrate and is formed to have a higher impurity concentration than the impurity concentration of the region adjacent to the through-electrode at the central portion of the semiconductor substrate.

(2) The image sensor according to (1), in which

the photoelectric conversion unit includes a photoelectric conversion film disposed adjacent to the back surface of the semiconductor substrate.

(3) The image sensor according to (1) or (2), in which

the through-electrode is formed by embedding a conductive material in a through-hole, the through-hole being formed in the semiconductor substrate and including an insulating film disposed on a wall surface thereof.

(4) The image sensor according to any one of (1) to (3), in which

the front-side high impurity concentration region is formed to have an impurity concentration of substantially 10¹⁷ cm⁻³ or more.

(5) The image sensor according to any one of (1) to (4), in which

the back-side high impurity concentration region is formed to have an impurity concentration of substantially 10¹⁸ cm⁻³ or more.

(6) The image sensor according to any one of (1) to (5), in which

the front-side high impurity concentration region is formed to have a thickness of substantially ⅙ of a thickness of the semiconductor substrate.

(7) The image sensor according to any one of (1) to (6), in which

the back-side high impurity concentration region is formed to have a thickness of substantially ⅙ of a thickness of the semiconductor substrate.

(8) The image sensor according to any one of (1) to (7), in which

the front-side high impurity concentration region is formed in a cylindrical shape surrounding the through-electrode and having a width equal to or larger than a diameter of the through-electrode.

(9) The image sensor according to any one of (1) to (8), in which

the back-side high impurity concentration region is formed in a cylindrical shape surrounding the through-electrode and having a width equal to or larger than a diameter of the through-electrode.

(10) The image sensor according to any one of (1) to (9), in which

the semiconductor substrate includes a region formed to have an impurity concentration of substantially 10¹⁶ cm⁻³ or more, the region being adjacent to the through-electrode between the front-side high impurity concentration region and the back-side high impurity concentration region.

(11) The image sensor according to any one of (1) to (10), further including

an image signal generation circuit that generates an image signal on the basis of the held charge.

(12) An imaging apparatus, including:

a photoelectric conversion unit that is disposed on a back surface of a semiconductor substrate and performs photoelectric conversion of incident light;

a through-electrode that is formed in a shape penetrating from the back surface to a front surface of the semiconductor substrate and transmits a charge generated by the photoelectric conversion;

a holding unit that is disposed on the front surface of the semiconductor substrate and holds the transmitted charge;

a back-side high impurity concentration region that is disposed in a region adjacent to the through-electrode on the back surface of the semiconductor substrate and is formed to have a higher impurity concentration than an impurity concentration of a region adjacent to the through-electrode at the central portion of the semiconductor substrate;

a front-side high impurity concentration region that is disposed in a region adjacent to the through-electrode on the front surface of the semiconductor substrate and is formed to have a higher impurity concentration than the impurity concentration of the region adjacent to the through-electrode at the central portion of the semiconductor substrate; and

a processing circuit that processes an image signal generated on the basis of the held charge.

### REFERENCE SIGNS LIST

1 image sensor
10 pixel array unit
30 column signal processing unit
100 pixel
101, 103, 105, 107 photoelectric conversion unit
102, 104, 106 charge transfer unit
110a, 110b, 110c image signal generation circuit
111a, 111b, 111c charge holding unit
120 semiconductor substrate
121 to 127 semiconductor region
128 front-side high impurity concentration region
129 back-side high impurity concentration region
133 separation region
138 through-electrode
139 through-hole
140 wiring region
141, 152 insulating layer
142, 154, 155 wiring layer
151, 162 insulating film
161 charge accumulation electrode
163 first electrode
164 photoelectric conversion film
165 second electrode
181 protective film
182 on-chip lens
1000 camera
1002 image sensor
1005 image processing unit
10402, 12031, 12101 to 12105 image pickup unit, imaging section

1. An image sensor, comprising:
a photoelectric conversion unit that is disposed on a back surface of a semiconductor substrate and performs photoelectric conversion of incident light;
a through-electrode that is formed in a shape penetrating from the back surface to a front surface of the semiconductor substrate and transmits a charge generated by the photoelectric conversion;
a charge holding unit that is disposed on the front surface of the semiconductor substrate and holds the transmitted charge;
a back-side high impurity concentration region that is disposed in a region adjacent to the through-electrode on the back surface of the semiconductor substrate and is formed to have a higher impurity concentration than an impurity concentration of a region adjacent to the through-electrode at the central portion of the semiconductor substrate; and
a front-side high impurity concentration region that is disposed in a region adjacent to the through-electrode on the front surface of the semiconductor substrate and is formed to have a higher impurity concentration than the impurity concentration of the region adjacent to the through-electrode at the central portion of the semiconductor substrate.

2. The image sensor according to claim 1, wherein
the photoelectric conversion unit includes a photoelectric conversion film disposed adjacent to the back surface of the semiconductor substrate.

3. The image sensor according to claim 1, wherein
the through-electrode is formed by embedding a conductive material in a through-hole, the through-hole being formed in the semiconductor substrate and including an insulating film disposed on a wall surface thereof.

4. The image sensor according to claim 1, wherein
the front-side high impurity concentration region is formed to have an impurity concentration of substantially 10¹⁷ cm⁻³ or more.

5. The image sensor according to claim 1, wherein
the back-side high impurity concentration region is formed to have an impurity concentration of substantially 10¹⁸ cm⁻³ or more.

6. The image sensor according to claim 1, wherein
the front-side high impurity concentration region is formed to have a thickness of substantially ⅙ of a thickness of the semiconductor substrate.

7. The image sensor according to claim 1, wherein
the back-side high impurity concentration region is formed to have a thickness of substantially ⅙ of a thickness of the semiconductor substrate.

8. The image sensor according to claim 1, wherein
the front-side high impurity concentration region is formed in a cylindrical shape surrounding the through-electrode and having a width equal to or larger than a diameter of the through-electrode.

9. The image sensor according to claim 1, wherein
the back-side high impurity concentration region is formed in a cylindrical shape surrounding the through-electrode and having a width equal to or larger than a diameter of the through-electrode.

10. The image sensor according to claim 1, wherein
the semiconductor substrate includes a region formed to have an impurity concentration of substantially 10¹⁶ cm⁻³ or more, the region being adjacent to the through-electrode between the front-side high impurity concentration region and the back-side high impurity concentration region.

11. The image sensor according to claim 1, further comprising
an image signal generation circuit that generates an image signal on a basis of the held charge.

12. An imaging apparatus, comprising:
a photoelectric conversion unit that is disposed on a back surface of a semiconductor substrate and performs photoelectric conversion of incident light;
a through-electrode that is formed in a shape penetrating from the back surface to a front surface of the semiconductor substrate and transmits a charge generated by the photoelectric conversion;
a holding unit that is disposed on the front surface of the semiconductor substrate and holds the transmitted charge;
a back-side high impurity concentration region that is disposed in a region adjacent to the through-electrode on the back surface of the semiconductor substrate and is formed to have a higher impurity concentration than an impurity concentration of a region adjacent to the through-electrode at the central portion of the semiconductor substrate;
a front-side high impurity concentration region that is disposed in a region adjacent to the through-electrode on the front surface of the semiconductor substrate and is formed to have a higher impurity concentration than the impurity concentration of the region adjacent to the through-electrode at the central portion of the semiconductor substrate; and
a processing circuit that processes an image signal generated on a basis of the held charge.
